(19) United States
(12) Patent Application Publication
(10) Pub. No.: US 2017/0137589 A1
(43) Pub. Date: May 18, 2017

(54) METHODS OF MODIFYING SURFACES OF STRUCTURES USED IN THE MANUFACTURE OF A SEMICONDUCTOR DEVICE VIA FLUORINATION

(71) Applicant: Samsung Electronics Co., Ltd., Suwon-si (KR)

(72) Inventors: Cesar M. GARZA, Austin, TX (US); Sungil AHN, Austin, TX (US)

(21) Appl. No.: 15/054,122

(22) Filed: Feb. 25, 2016

Related U.S. Application Data
(60) Provisional application No. 62/256,112, filed on Nov. 16, 2015.

(51) Int. Cl. C08J 7/12; B01D 67/00; H01L 21/673

(52) U.S. Cl. CPC C08J 7/126; H01L 21/67366; B01D 67/0093; B01D 2323/36; B01D 2323/46; C08J 2369/00; C08J 2377/06; C08J 2323/06; C08J 2323/12

(57) ABSTRACT

Methods are disclosed for modifying surfaces of a structure used in manufacturing semiconductor devices wherein the structures are formed from organic polymers. In addition to the surface of the structure, which is over a core, a portion of the structure slightly below the surface is also modified via fluorination of the organic polymer. The fluorination is achieved by exposing the structure to a mixture of gases including fluorine in a range from about 0.01% to about 10% and inert gas comprising a remainder of the mixture of gases. Fluorination occurs from the surface into the core to a depth of no more than about 1 micron and such that a portion of the core below more than 1 micron from the surface is not fluorinated.

### TECHNICAL FIELD

The present disclosure relates to methods of manufacturing semiconductor devices with structures formed from organic polymers that have a surface modified by fluorination.

### BACKGROUND

It is essential to keep matter (gases, particles, and other foreign objects) from contaminating wafers in the process of manufacturing semiconductor devices. As an example, a Front Opening Universal Pod (FOUP) is a carrier or an enclosure to keep contamination from the wafers as they move from step to step in the manufacturing process. FOUPs are made of an organic polymer material, typically polycarbonate, that has the desirable mechanical properties but not the desired surface properties to keep contamination out. The present disclosure provides methods for modifying the surface properties of such structures without impacting the desirable bulk properties of the material.

A membrane used for filtration in the manufacture of semiconductor devices often require time to be prepared by flushing fluids through the membrane. This present disclosure provides methods for modifying the surface properties of such structures without impacting the desirable bulk properties of the material such that the filter membranes require less time to be prepared and are more effective when used.

### SUMMARY

Exemplary embodiments of the inventive concept provide improved structures for manufacturing semiconductor devices by modifying surfaces of the structures via fluorination. In accordance with an aspect of the inventive concept, a method of modifying surfaces of a structure used in manufacturing a semiconductor device includes, but is not limited to, obtaining a structure with a surface over a core, which are formed from an organic polymer, and exposing the structure to a mixture of gases including F₂ and at least one inert, carrier, gas such that the organic polymer is fluorinated from the surface into the core to a depth of no more than about a few micrometers and such that a portion of the core below more than a few micrometers from the surface is not fluorinated. In some embodiments, the fluorination from the surface into the core occurs to a depth of no more than about 1 micron and such that a portion of the core below more than 1 micron is not fluorinated. In other embodiments, the fluorination from the surface into the core occurs to a depth of no more than about 500 nm and such that a portion of the core below more than 500 nm is not fluorinated. Examples of structures that benefit from such fluorination include, but are not limited to, a wafer carrier such as an FOUP, and a filtration membrane as well as the supporting frame and case for the filtration membrane. In one embodiment, the gases include F₂ in a range from about 0.01% to about 10% and a remainder of the gases includes at least one inert gas such as N₂ or He.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, as listed below.

FIG. 1 is a schematic chemical reaction showing fluorination of an organic polymer to yield a fluorinated carbon polymer

FIG. 2 is a graph showing the fluorination depth in nanometers over 30 minutes for an organic polymer after exposure to a mixture of gases including 0.25% F₂/99.75% N₂.

FIG. 3 is a graph showing increasing depth based on increased concentration of the F₂ in a mixture with N₂ wherein the F₂ is included in amounts of 0.25%, 0.5%, and 0.75%.

FIG. 4 is a depiction of a nylon molecule showing positive and negative poles.

FIG. 5 is a schematic depiction of a sieving filtration membrane.

FIG. 6 is a schematic depiction of a non-sieving filtration membrane.

FIG. 7 is an image of ultra pure polyethylene.

FIG. 8 is an image of the ultra pure polyethylene after fluorination.

FIG. 9 is a depiction of a polyvinylidene difluoride-like material molecule showing positive and negative poles.

### DETAILED DESCRIPTION OF THE PREFERRED EMBODIMENTS

Various exemplary embodiments will be described more fully hereinafter with reference to the accompanying drawings. The present inventive concept may, however, be embodied in many alternate forms and should not be construed as limited to the example embodiments set forth herein. Rather, these example embodiments are provided so that this description will be thorough and complete, and will fully convey the scope of the present inventive concept to those skilled in the art.

A method of modifying surfaces of a structure formed from an organic polymer is achieved by exposing the structure to a mixture of gases including F₂ and at least one inert gas such as N₂ or He. The structure has a surface around a core. The surface and the core are formed from the same material. The organic polymer is fluorinated from the surface but only slightly into the core such that the bulk of the structure remains unchanged. Examples of suitable organic polymers include aliphatic polymers, aromatic polymers, semi-aromatic polymers, and polyolefins. More specific examples include polycarbonate, polyethylene, polypropylene, and nylon.

The depth of the fluorination of the organic polymer is determined primarily by the percentage of the F₂ in the mixture of gases. To achieve a desired depth of fluorination such as a few microns, the percentage of F₂ in the mixture of gases may range from about 0.01% to about 10%. In other embodiments, the percentage of F₂ in the mixture of gases is present in an amount less than about 5% or less than about 3%, with a low endpoint of about 0.01% or about 0.025%. In one embodiment, shallow fluorination is achieved by mild fluorination such as use of a mixture of gases with F₂ in an amount of about 0.25% relative to the inert gas. The optimum ratio varies based on the particular organic polymer and the desired application. For example, if the organic polymer is a polyolefin such as polyethylene, which is used a filter membrane, or such as polypropylene, which is used as a support frame for the filter membrane, the concentrations may be about 1% F₂/99% N₂ or even less than 1% F₂ such as a mixture that is at a ratio of 0.25% F₂/99.75% N₂. Note that in examples referring to the amount of N₂ another inert gas may replace the N₂ such as He.

Complete fluorination may not occur and may not be desirable. Partial fluorination is sufficient to achieve the desired objectives. The extent of fluorination, which varies from polymer to polymer, is probably determined by the acidity of the hydrogen atom. At a practical level, the degree of fluorination is determined by the concentration of the F_{2,} and to a lesser extent, by the time the polymer is exposed to the F₂ gas. Complete fluorination does not take place due to increased electrostatic repulsion between adjacent fluorine atoms. If more aggressive fluorination conditions are used to overcome these repulsions, the fluorine will start breaking up carbon bonds in the main polymer chain. By controlling the fluorination process such that only mild fluorination occurs, the structure maintains its bulk properties. For example, after fluorination of a portion of an organic polymer from the surface into the core to a depth of no more than about 500 nm, the portion of the membrane that is below more than about 500 nm from the surface remains unaltered and is not fluorinated. In one embodiment, substitution of hydrogen atoms in a structure formed from polyethylene is controlled to yield partial fluorination just below the surface to form a material that resembles polyvinylidene difluoride (PVDF) in its stoichiometry.

The fluorination is controlled to occur at a depth of no more than a few microns, about two microns, about one micron, less than about one micron, no more than about 500 nm, or less than about 500 nm. However, shallower fluorination is generally sufficient. For example, the organic polymer may be fluorinated from the surface into the core to a depth in a range of about 50 nm to about 250 nm such as no more than about 200 nm or about 200 nm.

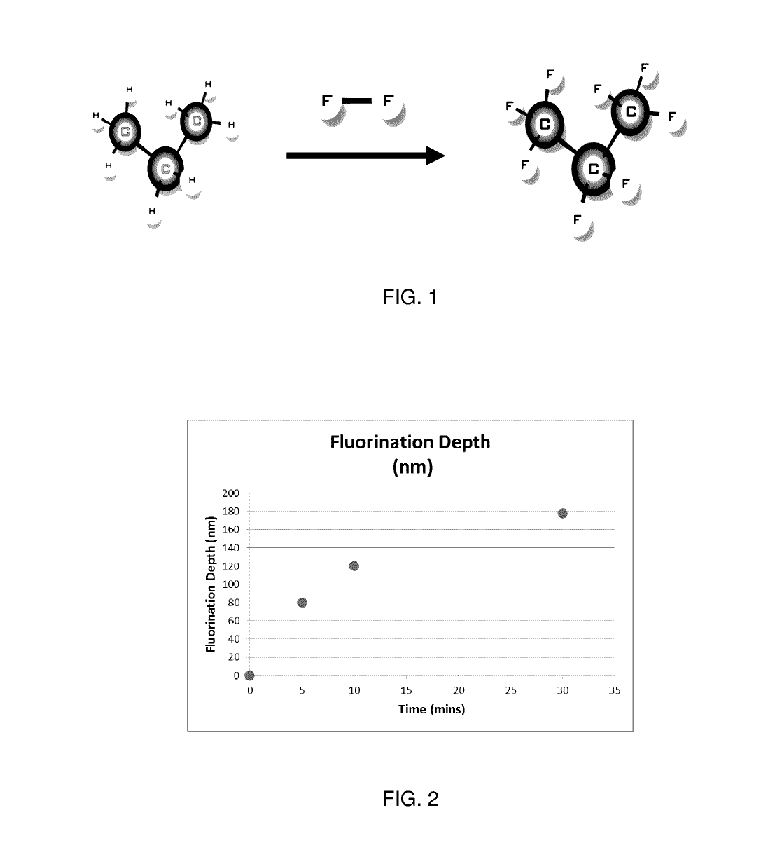

FIG. 1 shows the fluorination process for an organic polymer with the hydrogen atoms replaced by fluorine atoms. As provided below, this reaction proceeds via free radicals and takes place very rapidly.

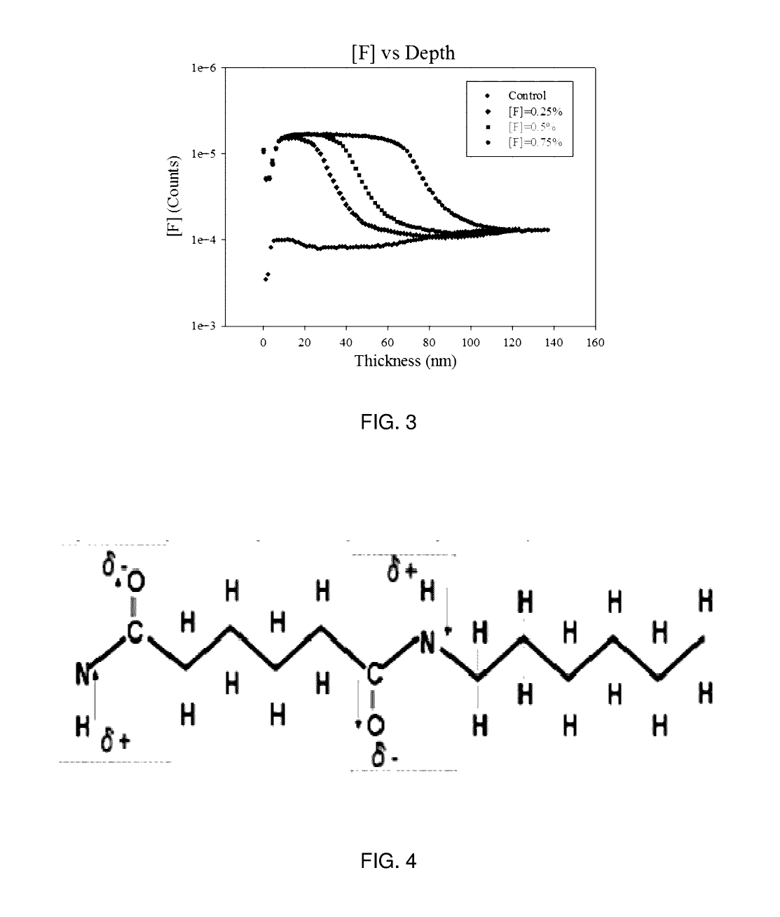

Data related to the kinetics of the reaction process suggests that it is diffusion limited and should follow Fick's law of diffusion and the fluorination depth is proportional to the square root of time. While the fluorination depth is primarily determined by the concentration of the fluorine in the mixture of gases, it is also controlled by time. FIG. 2 shows the depth of fluorination for a semi-aromatic aliphatic polymer exposed to a mixture of gases including 0.25% F₂ and 99.75% N₂ at room temperature, 25° C. The depth is plotted at intervals of 5 minutes, 10 minutes and 30 minutes. FIG. 3 shows increasing depth based on increased concentration of the F₂ for the semi-aromatic aliphatic polymer material and at the same temperature, 25° C. In particular, FIG. 3 shows the depth for concentrations of F₂ in a mixture with N₂ wherein the F₂ is included in amounts of 0.25%, 0.5%, and 0.75%.

To achieve the desired depth of fluorination, the organic polymer is exposed to a mixture of gases including F₂ and an inert gas for a period of time of no more than 1 hour. In another embodiment, the organic polymer is exposed to a mixture of gases including F₂ and an inert gas for a period of time ranging from about 30 seconds to about 15 minutes and in another embodiment, the exposure time ranges from about 5 minutes to about 15 minutes. In most embodiments, the exposure time is at least about 30 seconds.

The temperature during exposure of the mixture of gases to the organic polymer may range from about 0° C. to about 40° C. In one embodiment, the desirable temperature for exposure is at near room temperature, which is about 25° C.

The mild fluorination with partial penetration below the surface of a structure formed from an organic polymer as disclosed herein may be used to treat any structures formed from organic polymers in equipment used to process wafers for the manufacture of semiconductor devices. Such fluorination reduces the possibility of shedding particles and/or contamination when the structure comes in contact with chemicals used in the manufacture of semiconductor devices. Stated otherwise, the fluorination method disclosed herein enables the organic polymer to be “passivated.”

In one embodiment, a structure that is beneficially fluorinated is a wafer carrier such as an FOUP. FOUPs are formed from an organic polymer, which is most typically polycarbonate. Below is the chemical structure of polycarbonate

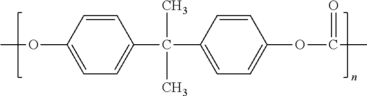

Exposure of the polycarbonate structure to a gas including F₂ and at least one inert gas modifies the surface to have a chemical structure of a fluorinated polycarbonate as provided below. While the formula shows complete fluorination; partial fluorination also provides an acceptable change.

By fluorinating a portion of a wafer carrier such as a wafer enclosure just below its surface, the surface modification will lead to reduced contamination by blocking the passing of contaminant gasses; some of which come from the wafers being carried by the carrier.

Examples of carriers and compositions for forming carriers are disclosed in U.S. Pat. No. 8,652,391, which is titled: “Method of Forming Substrate Carriers and Articles from Compositions Comprising Carbon Nanotubes.” U.S. Pat. No. 8,652,391, which is hereby incorporated by reference, mentions polyolefins blended with carbon nanotubes as a material for forming wafer enclosures, such as FOUPs.

In another embodiment, a structure that is beneficially fluorinated is a filter membrane. Filter membranes are formed from an organic polymer such as a polyolefin. In particular, the polyolefin may be polyethylene or nylon. An example of a polyethylene that is typically used includes ultra pure polyethylene. Exposing the polyethylene to F₂ yields a fluorinated surface, which in one embodiment resembles PVDF due to partial fluorination.

A filter membrane device may include a supporting frame around the filter membrane and a case. The supporting frame and case may also be formed from an organic polymer such that it may also be fluorinated. For example, the supporting frame and case may be formed from polyethylene or polypropylene.

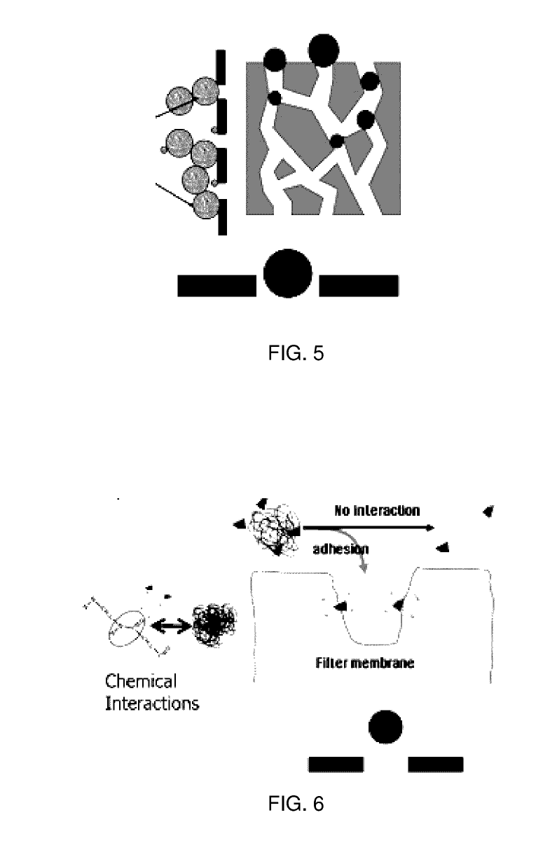

The filter membrane may be a sieving or a non-sieving filtration membrane. Sieving is the retention of particles that are larger than the pores of a filter. A sieving membrane is shown in FIG. 5 and a non-sieving membrane is shown in FIG. 6. A sieving membrane as shown in FIG. 5 enables particles to enter the membrane more easily than a non-sieving membrane as shown in FIG. 6. By fluorinating a portion of a filter membrane at the surface and just below the surface, the polymer morphology is changed as may be seen by comparing FIG. 5 and FIG. 6. The surface area increases and pores open up which enhances particle retention while minimizing pressure drop. Additionally, the fluorine will react and produce volatile products with contaminants, leachables, and extractables found on the surface of the membrane of the filter, supporting frame, and case, thereby reducing the amount of time needed for preparation to use the filter. Non-sieving filtration membranes often have a 35 nm node (70 nm pitch) but non-sieving filtration membranes are expected to more typically have a 14 nm node (28 nm pitch).

As the particle size decreases, another set of mechanisms known as non-sieving play an increasingly important role in the filter performance DLVO theory, amongst others, has been used to describe non-sieving retention through particle adsorption mechanisms to membrane surfaces. Adsorption is a surface phenomenon; it is a consequence of surface energy. By fluorinating a portion of a filter membrane at the surface and just below the surface, the surface energy of a polymer like polyethylene increases to more than 40 mN/m.

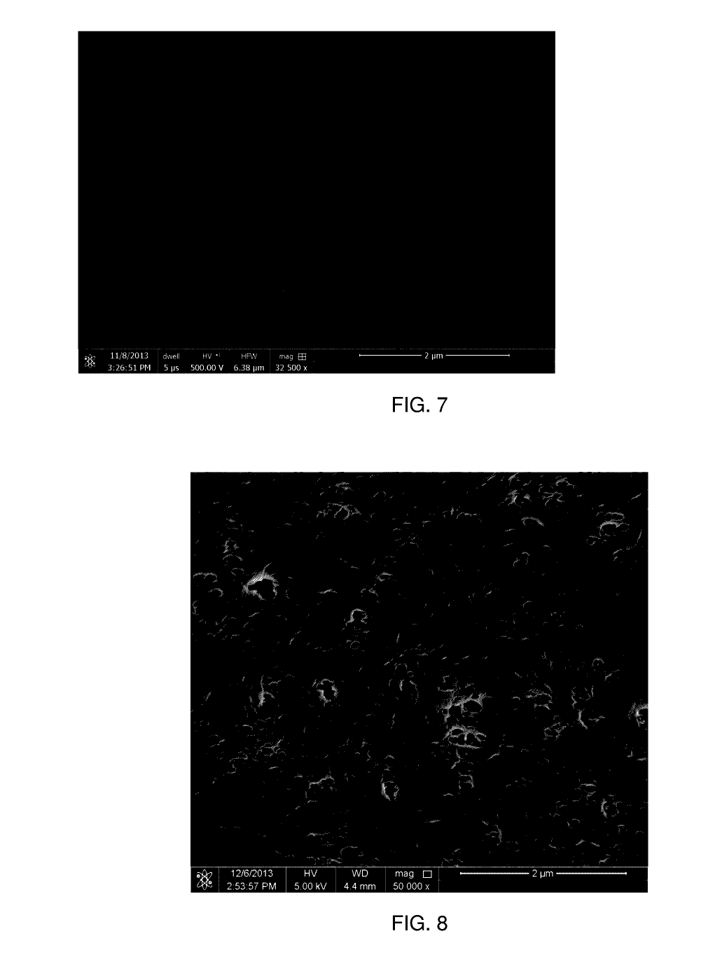

The sample brightness of a specimen under an SEM may be used as a rough estimate of the surface energy: the brighter the sample the higher the surface energy. For example, FIG. 7 shows an enlarged image using scan electron microscopy, SEM, of ultra pure polyethylene before fluorination, while FIG. 8 shows an enlarged image using scan electron microscopy, SEM, of ultra pure polyethylene after fluorination. The fluorination conditions were F₂=0.075%/N₂=99.925% for 15 minutes at room temperature. The magnification of the image in FIG. 7 is 32,500× and the magnification in FIG. 8 is 50,000×. In both instances the distance of 2 micrometers is shown as a reference. As shown in the SEMs shown in FIG. 7 and FIG. 8, the fluorinated sample has a higher surface energy. The increased surface energy resulting from fluorination enhances particle adhesion, improving the filter performance

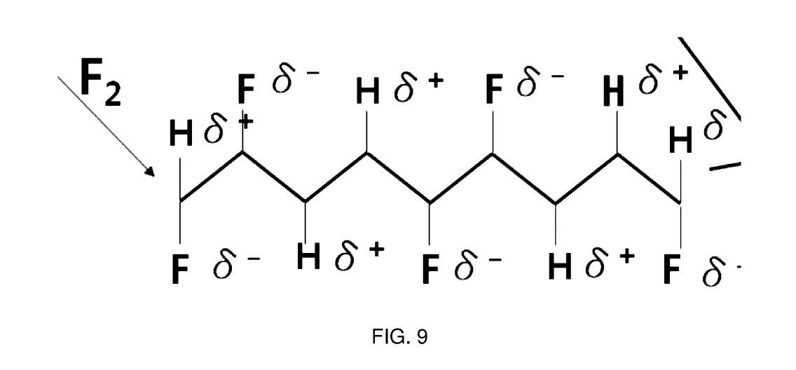

Fluorination also modifies the surface and a portion of the bulk of the structure below the surface in other ways. It is also advantageous to have positive and negative poles like the nylon as shown in FIG. 4. For example, FIG. 9 shows the poles and the polarity gradient after fluorination. The polarity gradient increase chemical interactions and enhances the ability of the fluorinated filter membranes to filter out undesired chemicals.

The polarity of the membrane may be tuned such that the fluorinated portion has greater polarity than the portion that is not fluorinated. This may be due to the polarity of the chemical moieties, which is determined by the electronegativity of the atoms involved in the chemical bonds. For instance, nylon is a material commonly used to make filter membranes. The structure of nylon is shown in FIG. 4 with the polarities indicated. According to Pauli's electronegativity scale, oxygen has a value of 3.5, second only to fluorine (4.0). Nitrogen has a value of 3.0 compared to hydrogen that has only a value of 2.1. Thus there will be positive and negative polarity in these bonds that may interact with a material of the opposite charge, leading to its adsorption.

Any methods disclosed herein comprise one or more steps or actions for performing the described method. The method steps and/or actions may be interchanged with one another. In other words, unless a specific order of steps or actions is required for proper operation of the embodiment, the order and/or use of specific steps and/or actions may be modified.

References to approximations are made throughout this specification, such as by use of the terms “about” or “approximately.” For each such reference, it is to be understood that, in some embodiments, the value, feature, or characteristic may be specified without approximation. For example, where qualifiers such as “about,” “substantially,” and “generally” are used, these terms include within their scope the qualified words in the absence of their qualifiers.

Reference throughout this specification to “an embodiment” or “the embodiment” means that a particular feature, structure or characteristic described in connection with that embodiment is included in at least one embodiment. Thus, the quoted phrases, or variations thereof, as recited throughout this specification are not necessarily all referring to the same embodiment.

Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, as the following claims reflect, inventive aspects lie in a combination of fewer than all features of any single foregoing disclosed embodiment.

The claims following this written disclosure are hereby expressly incorporated into the present written disclosure, with each claim standing on its own as a separate embodiment. This disclosure includes all permutations of the independent claims with their dependent claims. Moreover, additional embodiments capable of derivation from the independent and dependent claims that follow are also expressly incorporated into the present written description. These additional embodiments are determined by replacing the dependency of a given dependent claim with the phrase “any of the preceding claims up to and including claim [x],” where the bracketed term “[x]” is replaced with the number of the most recently recited independent claim. For example, for the first claim set that begins with independent claim 1, claim 3 may depend from either of claims 1 and 2, with these separate dependencies yielding two distinct embodiments; claim 4 may depend from any one of claim 1, 2, or 3, with these separate dependencies yielding three distinct embodiments; claim 5 may depend from any one of claim 1, 2, 3, or 4, with these separate dependencies yielding four distinct embodiments; and so on.

Recitation in the claims of the term “first” with respect to a feature or element does not necessarily imply the existence of a second or additional such feature or element. Elements specifically recited in means-plus-function format, if any, are intended to be construed in accordance with 35 U.S.C. §112 ¶6. Embodiments of the invention in which an exclusive property or privilege is claimed are defined as follows.

1. A method, comprising:
obtaining a structure configured to be used in manufacturing a semiconductor device, wherein the structure comprises a surface over a core, wherein the core and the surface are formed from an organic polymer;
exposing the structure to a mixture of gases comprising F₂ and at least one inert gas such that the organic polymer is fluorinated from the surface into the core to a depth of no more than about 1 micron and such that a portion of the core below more than 1 micron from the surface is not fluorinated, wherein the mixture of gases comprises F₂ in a range from about 0.01% to about 10% and the inert gas comprises a remainder of the mixture of gases.

2. The method of claim 1, wherein the organic polymer is at least one of aliphatic polymers, aromatic polymers, semi-aromatic polymers, and polyolefins.

3. The method of claim 2, wherein the polyolefin is at least one of polycarbonate, polyethylene, polypropylene, and nylon.

4. The method of claim 1, wherein the inert gas comprises at least one of N₂ and He.

5. The method of claim 1, wherein the gas comprises F₂ in an amount less than about 5%.

6. The method of claim 1, wherein the gas comprises F₂ in an amount less than about 3%.

7. The method of claim 1, wherein the gas comprises F₂ in an amount of about 0.25.

8. The method of claim 1, wherein the organic polymer is fluorinated from the surface into the core to a depth in a range of about 50 nm to about 250 nm.

9. The method of claim 1, wherein the organic polymer is exposed to the mixture of gases for a period of time of no more than 1 hour.

10. The method of claim 1, wherein the organic polymer is exposed to the mixture of gases for a period of time ranging from about 30 seconds to about 15 minutes.

11. The method of claim 1, wherein the structure is exposed to the gas at a temperature that is near room temperature.

12. A method, comprising:
obtaining an enclosure configured to hold a silicon wafer, wherein the enclosure comprises a surface over a core, wherein the core and the surface are formed from a polycarbonate;
exposing the enclosure to a mixture of gases comprising F₂ and an inert gas such that the polycarbonate is fluorinated from the surface into the core to a depth of no more than about 500 nm, wherein the mixture of gases comprises F₂ in a range from about 0.01% to about 10% and the inert gas comprises a remainder of the mixture of gases.

13. The method of claim 12, wherein the enclosure is a front opening unified pod.

14. The method of claim 12, wherein the gas comprises F₂ in an amount of about 0.25%.

15. A method, comprising:
obtaining a membrane configured for use as a filter in manufacturing a semiconductor device, wherein the membrane comprises a surface over a core, wherein the core and the surface are formed from a polyolefin;
exposing the membrane to a mixture of gases comprising F₂ and an inert gas such that the polyolefin is fluorinated from the surface into the core to a depth of no more than about 500 nm, wherein the mixture of gases comprises F₂ in an amount less than 1% by volume of the gas and the inert gas comprises a remainder of the mixture of gases.

16. The method of claim 15, wherein the organic polymer is polyolefin is at least one of polyethylene and nylon.

17. The method of claim 15, wherein the gas comprises F₂ in an amount of about 0.25%.

18. The method of claim 16, wherein the membrane is a non-sieving filtration membrane.

19. The method of claim 15, wherein the surface has a smaller pore size after being exposed to the gas relative to the pore size of the core.

20. The method of claim 16, wherein the membrane is a non-sieving filtration membrane, and wherein after fluorination a portion of the polyolefin from the surface into the core to a depth of no more than about 500 nm has a smaller pore size and is more polar than a portion of the membrane that is below more than about 500 nm from the surface.
